(19) United States
(12) Patent Application Publication
(10) Pub. No.: US 2007/0086150 A1
(43) Pub. Date: Apr. 19, 2007

(54) Rotating and sliding module for a display panel

(75) Inventors: Cheng-Chung Chu, Peitou (TW); Yuan Yu, Peitou (TW); Chui-Lang Huang, Peitou (TW)

Correspondence Address: BIRCH STEWART KOLASCH & BIRCH, PO BOX 747, FALLS CHURCH, VA, 22040-0747, US

(73) Assignee: ASUSTek COMPUTER INC.

(21) Appl. No.: 11/506,861

(22) Filed: Aug. 21, 2006

(30) Foreign Application Priority Data
Oct. 13, 2005 (TW) 94135736

(51) Int. Cl. H05K 5/00

(52) U.S. Cl. 361/679

(57) ABSTRACT

The present invention provides a rotating and sliding module that includes a sliding part and a rotating part coupling with the sliding part. The rotating part may rotate the display panel and slide the display panel along the sliding part to adjust the viewing angle of the display panel.

### RELATED APPLICATIONS

The present application is based on, and claims priority from, Taiwan Application Serial Number 94135736, filed Oct. 13, 2005, the disclosure of which is hereby incorporated by reference herein in its entirety.

### FIELD OF THE INVENTION

The present invention is related to a rotating and sliding module for a display panel, and more particularly to a rotating and sliding module for a liquid crystal display panel installed in a portable device.

### BACKGROUND OF THE INVENTION

Many advantages exist of a liquid crystal display panel (LCD), such as high display panel quality, small volume, low weight, low voltage driving, and low power consumption. Therefore, LCDs have been extensively used in various portable electrical devices, such as mobile phones and notebooks.

Typically, the LCD is embedded in a fixed type or sliding type mobile phone shield. Therefore, a user has to move the whole mobile phone to adjust the viewing angle. For example, the mobile phone has to be rotated 90 degrees when a user wants to display panel a movie. At this moment, if the user wants to use the mobile phone for a call, he has to operate the keyboard in an awkward position, which is very inconvenient.

Therefore, it is the goal for a designer to create a mobile phone with an LCD that can be freely adjusted by a user for changing its viewing angle and location.

### SUMMARY OF THE INVENTION

Therefore, the purpose of the present invention is to provide a rotating and sliding module used in an operation interface for moving and rotating a display panel.

The other purpose of the present invention is to provide a rotating and sliding module for adjusting the viewing angle and the distance of a display panel.

According to the foregoing purposes, the embodiment of the present invention provides a rotating and sliding module that includes a sliding part and a rotating part coupling with the sliding part. The rotating part may slide a display panel along the sliding part and rotate the display panel to adjust the positioning angle of the display panel.

The embodiment of the present invention also provides a mobile phone with an adjustable display panel. This mobile phone includes a base, a display panel and a rotating and sliding module. The rotating and sliding module connects the base and the display panel. The rotating and sliding module includes a sliding part and a rotating part coupling with the sliding part. The rotating part may rotate the display panel and slide the display panel along the sliding part to adjust the positioning angle of the display panel.

### BRIEF DESCRIPTION OF THE DRAWINGS

The foregoing aspects and many of the attendant advantages of this invention will become more readily appreciated and better understood by referencing the following detailed description, when taken in conjunction with the accompanying drawings, wherein:

FIG. 1 is an exploded view of a mobile phone with a rotating and sliding module according to a preferred embodiment of the present invention;

FIG. 2 is an exploded view of a rotating and sliding module according to a preferred embodiment of the present invention;

FIG. 3 illustrates an assembly excluding the upper cover of a sliding part according to a preferred embodiment of the present invention;

FIG. 4 illustrates an assembly of a rotating and sliding module according to a preferred embodiment of the present invention;

FIGS. 5a to 5e illustrate schematic diagrams of a mobile phone being moved by the rotating and sliding module of the present invention; and

FIGS. 6a to 6e illustrate schematic diagrams of the rotating and sliding module through the stages illustrated in FIGS. 5a to 5e.

### DETAILED DESCRIPTION OF THE PREFERRED EMBODIMENT

The following is a preferred embodiment of the present invention.

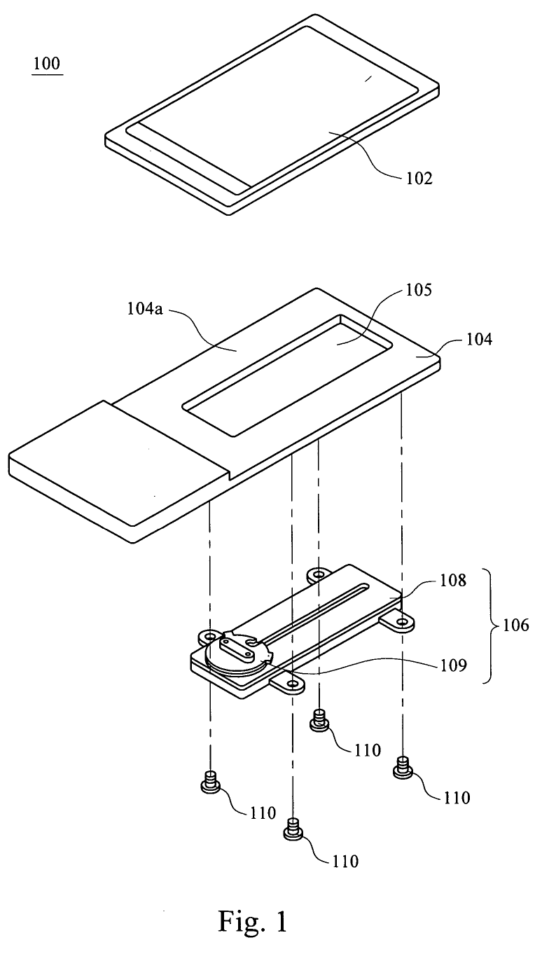

FIG. 1 is an exploded view of a mobile phone with a rotating and sliding module according to the preferred embodiment of the present invention. In this figure, the mobile phone 100 includes a display panel module 102, a base module 104 and a rotating and sliding module 106.

In this embodiment, one side of the base module 104 has a recessed region 104a. The display panel module 102 is located in the recessed region 104a. A trench 105 passing through the recessed region 104a is formed in the recessed region 104a. The rotating and sliding module 106 includes a sliding part 108 and a rotating part 109. The rotating part 109 is movable along the sliding part 108. The rotating and sliding module 106 is fixed in one side of the base module 104 by screws 110. In this case, the sliding part 108 is located and fixed in the trench 105 and the rotating part 109 protrudes out of the upper surface of the recessed region 104a of the base module 104. The display panel module 102 is coupled to the rotating part 109. Therefore, the display panel module 102 may be moved and rotated by the rotating part 109 along the trench 105. A cover (not shown in this figure) of a portable apparatus is fixed over the bottom of the base module 104 for covering the rotating and sliding module 106.

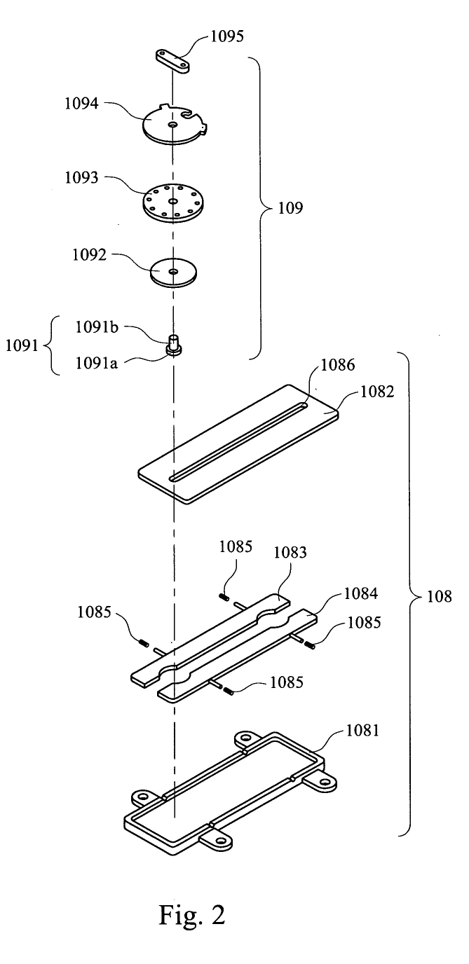

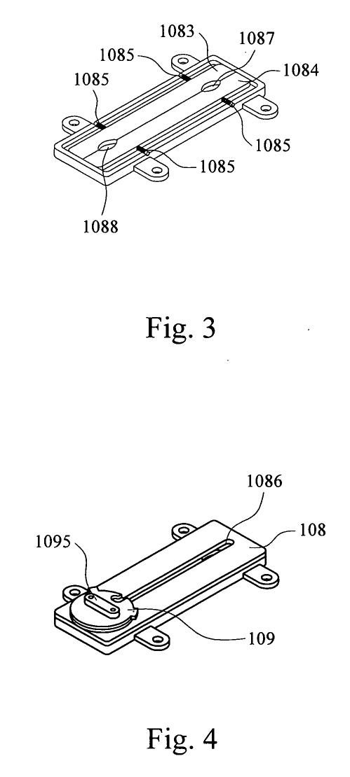

FIG. 2 is an exploded view of a rotating and sliding module according to the preferred embodiment of the present invention. In this figure, the rotating and sliding module 106 includes a sliding part 108 and a rotating part 109. The sliding part 108 includes a carrier 1081, a cover 1082, two sliding pieces 1083 and 1084 and a plurality of elastic apparatuses 1085. Each sliding piece includes two U-shaped recesses. Each elastic apparatus 1085 is a spring or a twisted. The two sliding pieces 1083 and 1084 are located in the carrier 1081. The elastic apparatuses 1085 are respectively located between the sliding piece 1083 and the corresponding sidewall of the carrier 1081 and between the sliding piece 1084 and the corresponding sidewall of the carrier 1081. In other words, the two ends of the elastic apparatuses 1085 are respectively coupled to the sliding piece 1083 or 1094 and the sidewall of the carrier 1081. In this case, the elastic force of these elastic apparatuses 1085 helps the two sliding pieces 1083 and 1084 stay together to form a track in the coupling face. Moreover, when held together, the corresponding U-shaped recesses of the two sliding pieces 1083 and 1084 are closed together to form two fixed positions 1087 and 1088 (as shown in FIG. 3).

The cover 1082 and the carrier 1081 shield the two sliding pieces 1083 and 1084 and the elastic apparatuses 1085. An opening 1086 is formed in the cover 1082 to expose the track formed by the two sliding pieces 1083 and 1084 and limits the moving direction of the rotating part 109. FIG. 3 illustrates an assembly of the sliding part 108 according to the preferred embodiment of the present invention (the cover 1082 is not shown in this figure).

Referring to FIG. 2 again, the rotating part 109 includes a rotating axis 1091, a rotating base 1092, a positioner 1093, a cover 1094 and a fixed tenon 1095. The bottom 1091a of the rotating axis 1091 is located in the track of the sliding part 108. The bottom 1091a may be moved between the two fixed positions 1087 and 1088. The axle 1091b extends through the opening 1086. Many positions exist in the positioner 1093 that is located between the cover 1094 and the rotating base 1092 to orient the position. The axle 1091 b passes through the center of the rotating base 1092, the positioner 1093 and the cover 1094, and is fixed to the fixed tenon 1095. The axle 1091b is used as an axis. The fixed tenon 1095 is located over the cover 1094 to couple with the display panel module 102 as shown in FIG. 1. The rotating part 109 can rotate the display panel module 102 from −90 degrees to 90 degrees. It is noticed that other types of design of the rotating part also can be used in the present invention.

FIG. 4 illustrates an assembly of a rotating and sliding module 106 according to the preferred embodiment of the present invention. The fixed tenon 1095 couples with the display panel module 102 of FIG. 1. The rotating part 109 may rotate the display panel module 102 and bring the display panel module to move along the opening 1086 of the sliding part 108.

The operation of the sliding part 108 and the rotating part 109 is described as follows. Reference is again made to FIGS. 2 and 3. The rotating axis 1091 is slid from the fixed position 1088 to the fixed position 1087. When the bottom 1091 a of the rotating axis 1091 slides out the fixed position 1088, the elastic apparatuses 1085 are deformed, wherein the deformed volumes of the elastic apparatuses near the fixed position 1088 are larger than near the fixed position 1087. When the bottom 1091a slides to the center of the track, the elastic apparatuses 1085 have the same deformed volumes. When the bottom 1091a slides over the center of the track, the deformed volumes of the elastic apparatuses near the fixed position 1088 are less than near the fixed position 1087. After the bottom 1091a slides over a certain distance of the track, the restoring force of the elastic apparatuses push the bottom 1091a to the fixed position 1087.

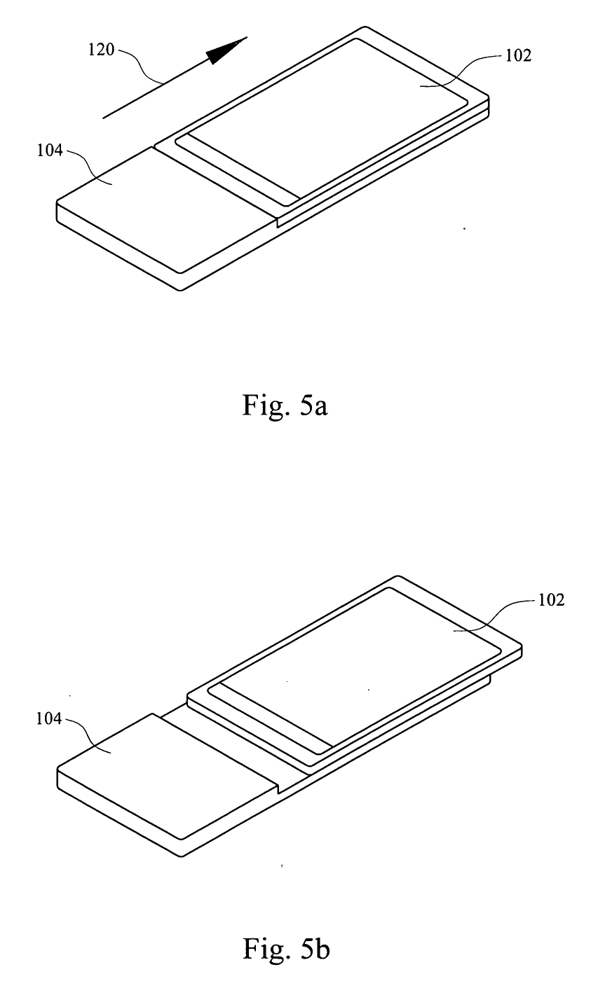

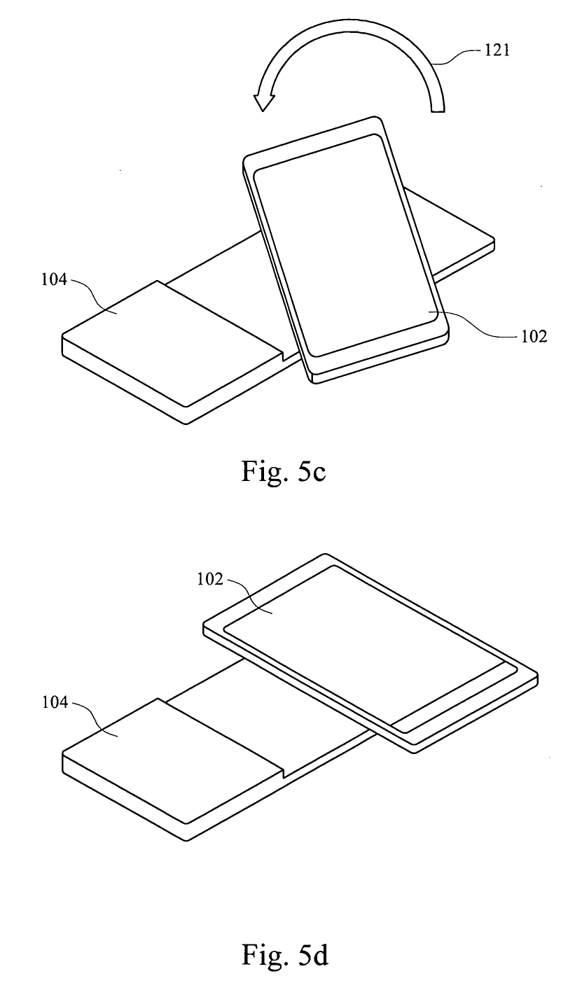

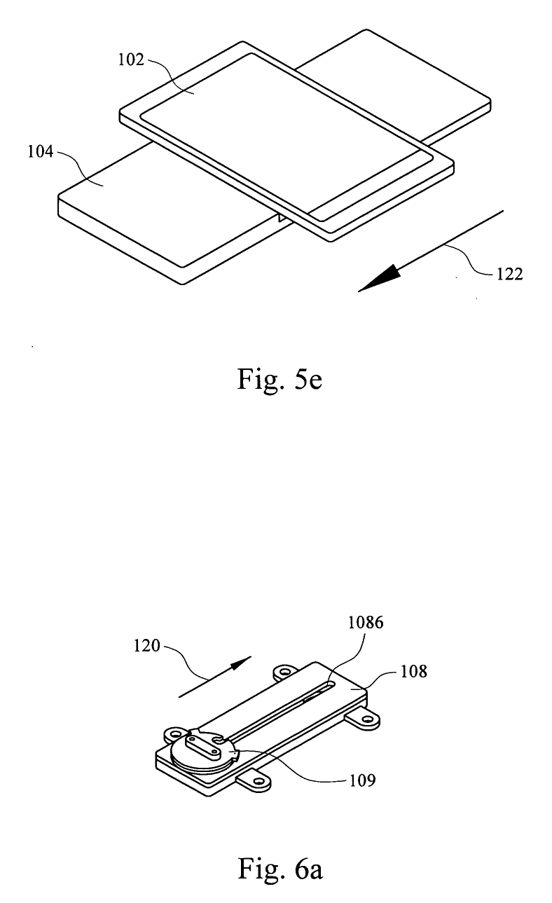

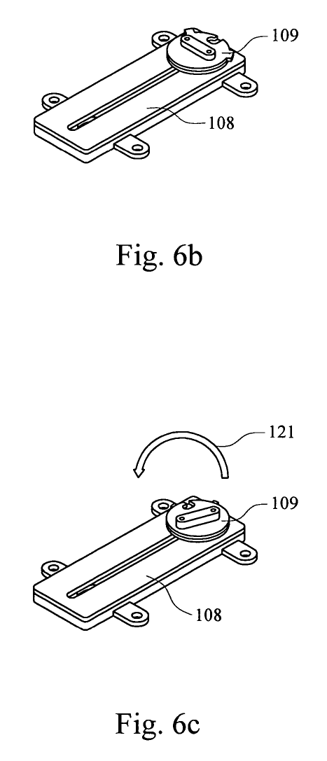

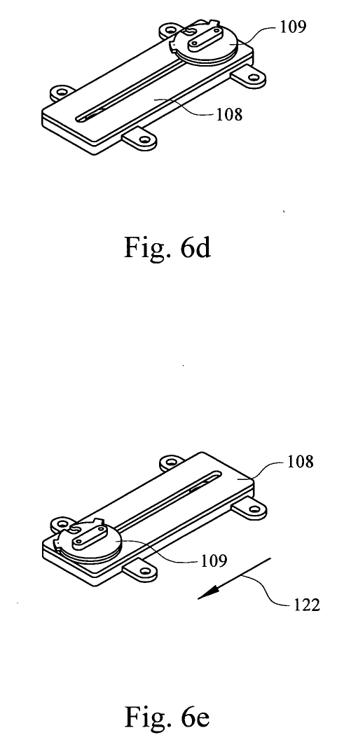

FIGS. 5a to 5e illustrate a mobile phone being moved by the rotating and sliding module 106 of the present invention. Reference is also made to FIGS. 6a to 6e, which illustrate the rotating and sliding module 106 being moved through the stages shown in FIG. 5. In FIG. 5a, when the display panel module 102 is pushed along the direction of the arrow 120, the rotating module 109 is moved along the opening 1086 of the sliding part 108 from the position shown in FIG. 6a to the position shown in FIG. 6b. In this case, the display panel module 102 is moved to the position shown in FIG. 5b. Next, in FIG. 5c, when the display panel module 102 is rotated along the direction of the arrow 121, the rotating module 109 is rotated 90 degrees from the position shown in FIG. 6c to the position shown in FIG. 6d. In this case, the display panel module 102 is rotated to the position shown in FIG. 5d. Finally, when the display panel module 102 is pushed along the direction of the arrow 122 in FIG. 5e, the rotating module 109 is moved along the opening 1086 of the sliding part 108 to the position shown in FIG. 6e. In this case, the display panel module 102 is moved to the position shown in FIG. 5e.

Accordingly, the rotating and sliding module of the present invention can rotate and move a display panel module. Therefore, it can completely adjust not only the location but also the viewing angle. In other words, the user may dynamically change the viewing angle and location of the display panel according to his preference.

As is understood by a person skilled in the art, the foregoing descriptions of the preferred embodiment of the present invention are an illustration of the present invention rather than a limitation thereof. Various modifications and similar arrangements are included within the spirit and scope of the appended claims. The scope of the claims should be accorded to the broadest interpretation so as to encompass all such modifications and similar structures. While a preferred embodiment of the invention has been illustrated and described, it will be appreciated that various changes can be made therein without departing from the spirit and scope of the invention.

What is claimed is:

1. A rotating and sliding module coupling with a display panel, comprising:
a rotating part coupling with said display panel, wherein said rotating part is used as an axis to rotate said display panel; and
a sliding part coupling with said rotating part, wherein said rotating part may slide said display panel along said sliding part.

2. The rotating and sliding module of claim 1, wherein said sliding part includes a shield and two sliding pieces arranged in parallel and located in the shield, a track for sliding said rotating part is formed in the adjoining face of said two sliding pieces.

3. The rotating and sliding module of claim 2, further comprising a plurality of elastic apparatuses located between said shield and said two sliding pieces respectively, a restoring force of said elastic apparatuses may help to butt together said two sliding pieces.

4. The rotating and sliding module of claim 3, wherein each of said plurality of elastic apparatuses is a spring.

5. The rotating and sliding module of claim 3, wherein each of said plurality elastic apparatuses is a twisted.

6. The rotating and sliding module of claim 3, wherein said sliding pieces further comprise a fixed position, and said restoring force may move said rotating part to said fixed position after said rotating part is slid to a certain distance in said track.

7. The rotating and sliding module of claim 3, wherein said sliding pieces further comprise two fixed positions for locating said rotating part.

8. The rotating and sliding module of claim 1, wherein said rotating part may rotate said display panel from −90 degrees to 90 degrees.

9. The rotating and sliding module of claim 1, wherein said rotating part includes an axle and said axle is used as an axis to rotate said display panel.

10. A rotating and sliding module used in a portable device, wherein said portable device includes a base and a display panel, said module comprising:
a rotating part coupling with said display panel, wherein said rotating part is used as an axis to rotate said display panel; and
a sliding part fixed in said base and coupling with said rotating part, wherein said rotating part comprises:
a shield; and
two sliding pieces arranged in parallel and located in the shield, and a track for sliding said rotating part is formed in the adjoining face of said two sliding pieces.

11. The rotating and sliding module of claim 10, further comprising a plurality of elastic apparatuses located between said shield and said two sliding pieces respectively, a restoring force of said elastic apparatuses may help to butt together said two sliding pieces.

12. The rotating and sliding module of claim 11, wherein each of said plurality of elastic apparatuses is spring.

13. The rotating and sliding module of claim 11, wherein each of said plurality of elastic apparatuses is a twisted.

14. The rotating and sliding module of claim 11, wherein said sliding pieces further comprise a fixed position, and said restoring force may move said rotating part to said fixed position after said rotating part is slid to a certain distance in said track.

15. The rotating and sliding module of claim 11, wherein said sliding pieces further comprise two fixed positions for locating said rotating part.

16. The rotating and sliding module of claim 10, wherein said rotating part may rotate said display panel from −90 degrees to 90 degrees.

17. The rotating and sliding module of claim 10, wherein said rotating part includes an axle and said axle is used as an axis to rotate said display panel.

18. A portable device, comprising:
a display panel;
a base; and
a rotating and sliding module coupling with said display panel and said base, wherein said rotating and sliding module comprises:
a rotating part coupling with said display panel, wherein said rotating part is used as an axis to rotate said display panel; and
a sliding part fixed in said base and coupling with said rotating part, wherein said rotating part includes a shield and two sliding pieces arranged in parallel and located in the shield, and a track is formed in the adjoining face of said two sliding pieces and exposes said shield, said rotating part may slide in said track.

19. The portable device of claim 18, further comprising a plurality of elastic apparatuses located between said shield and said two sliding pieces respectively, a restoring force of said elastic apparatus may help to butt together said two sliding pieces.

20. The portable device of claim 19, wherein each of said plurality of elastic apparatuses is spring.

21. The portable device of claim 19, wherein each of said plurality of elastic apparatuses is a twisted.

22. The portable device of claim 19, wherein said sliding pieces further comprise a fixed position, and said restoring force may move said rotating part to said fixed position after said rotating part is slid to a certain distance in said track.

23. The portable device of claim 19, wherein said sliding pieces further comprise two fixed positions for locating said rotating part.

24. The portable device of claim 18, wherein said rotating part may rotate said display panel from −90 degrees to 90 degrees.

25. The portable device of claim 18, wherein said rotating part includes an axle and said axle is used as an axis to rotate said display panel.
